(19) United States
(12) Patent Application Publication
(10) Pub. No.: US 2017/0154768 A1
(43) Pub. Date: Jun. 1, 2017

(54) CLEANING METHOD

(71) Applicant: DISCO CORPORATION, Tokyo (JP)

(72) Inventor: Jinyan Zhao, Tokyo (JP)

(21) Appl. No.: 15/357,503

(22) Filed: Nov. 21, 2016

(30) Foreign Application Priority Data
Nov. 26, 2015 (JP) 2015-230464

(51) Int. Cl. H01L 21/02; H01L 21/683; H01L 21/67; B08B 3/12; B08B 3/08

(52) U.S. Cl. CPC H01L 21/02076; B08B 3/12; B08B 3/08; H01L 21/67057; H01L 21/67236; H01L 21/6836; H01L 2221/68327

(57) ABSTRACT

A method of cleaning an object that includes a plurality of chips divided individually, starting from modified layers, and integral with a holding member, includes the steps of placing the object in a cleaning tank filled with a cleaning liquid which contains a surface active agent, and cleaning away modified layer debris on side faces of the chips with ultrasonic waves generated by ultrasonic oscillating means.

### BACKGROUND OF THE INVENTION

Field of the Invention

The present invention relates to a cleaning method for cleaning an object after it has been divided into chips.

Description of the Related Art

In recent years, there has been known a method of dividing a workpiece such as a wafer or the like by forming modified layers within the workpiece along projected dicing lines thereon and applying an external force to the workpiece to divide the workpiece into individual chips (see, for example, Japanese Patent No. 3408805). According to the dividing method disclosed in Japanese Patent No. 3408805, a laser beam having a wavelength (e.g., 1064 nm) that permeates the wafer is focused within the wafer to form the modified layers along the projected dicing lines. The external force is then applied to the wafer by breaking or the like to rupture the wafer, starting from the modified layers where the mechanical strength has been made lower.

Modified layer debris (diced debris) is likely to remain on the side faces (diced sectional faces) of the chips thus divided. The modified layer debris left on the side faces of the chips tends to contaminate the inside of the apparatus involved in subsequent steps such as a pick-up step, and also to contaminate even wafers to be processed later. Since the divided chips are closely spaced from each other, it is difficult to remove the modified layer debris left on the side faces of the chips even when the divided wafer is cleaned. There has been proposed a method of cleaning the modified layer debris left on the side faces of the chips by ejecting cleaning air from a nozzle toward the side faces of the chips while the divided chips are being picked up (see, for example, Japanese Patent Laid-Open No. 2013-105823).

### SUMMARY OF THE INVENTION

However, the cleaning method disclosed in Japanese Patent Laid-Open No. 2013-105823 is problematic in that the period of time required to clean the chips is long because it is necessary to pick up the divided chips one by one and to apply the cleaning air from the nozzle individually to the chips.

It is therefore an object of the present invention to provide a cleaning method which is capable of preventing modified layer debris from remaining on the side faces of divided chips and shortening the period of time required to clean the chips.

In accordance with an aspect of the present invention, there is provided a method of cleaning an object in which a plurality of chips, with modified layers formed on side faces of each of the chips, are integrally bonded to a holding member with spaces formed between adjacent ones of the chips, using a cleaning apparatus having a cleaning tank storing a cleaning liquid which contains a surface active agent and ultrasonic oscillating means disposed on a bottom or a side of the cleaning tank, the method including a placing step of placing the object in the cleaning tank and immersing the object in the cleaning liquid, and a cleaning step of cleaning away modified layer debris on side faces of the chips with ultrasonic waves generated by the ultrasonic oscillating means after performing the placing step.

In the above cleaning method, the object to be cleaned is immersed in the cleaning liquid containing the surface active agent, and the spaces between adjacent ones of the chips of the object are filled with the cleaning liquid. When the ultrasonic waves are applied to the cleaning liquid between the chips, the modified layer debris is well peeled off the side faces of the chips by a synergistic effect of an ultrasonic cleaning process and the surface active agent. Since all the chips of the object can simultaneously be cleaned, the period of time required to clean the chips can be greatly shortened compared with a process wherein the chips are picked up one by one from the object and individually cleaned.

The above and other objects, features and advantages of the present invention and the manner of realizing them will become more apparent, and the invention itself will best be understood from a study of the following description and appended claim with reference to the attached drawings showing a preferred embodiment of the invention.

### BRIEF DESCRIPTION OF THE DRAWINGS

FIG. 1 is a schematic cross-sectional view of an object to be cleaned by a cleaning method according to an embodiment of the present invention;

FIG. 2 is a schematic cross-sectional view of a cleaning apparatus for carrying out the cleaning method according to the embodiment;

FIG. 3 is an enlarged fragmentary cross-sectional view illustrative of the manner in which chips are cleaned by the cleaning method according to the embodiment;

FIG. 4 is a cross-sectional view showing by way of example a modified layer forming step of the cleaning method according to the embodiment;

FIGS. 5A and 5B are cross-sectional views showing by way of example a dicing step of the cleaning method according to the embodiment;

FIG. 6 is a cross-sectional view showing by way of example an inter-chip space holding step of the cleaning method according to the embodiment;

FIGS. 7A and 7B are cross-sectional views showing by way of example a placing step and a cleaning step, respectively, of the cleaning method according to the embodiment; and

FIG. 8 is a graph showing the relationship between cleaning methods and linear densities of modified layer debris.

### DETAILED DESCRIPTION OF THE PREFERRED EMBODIMENT

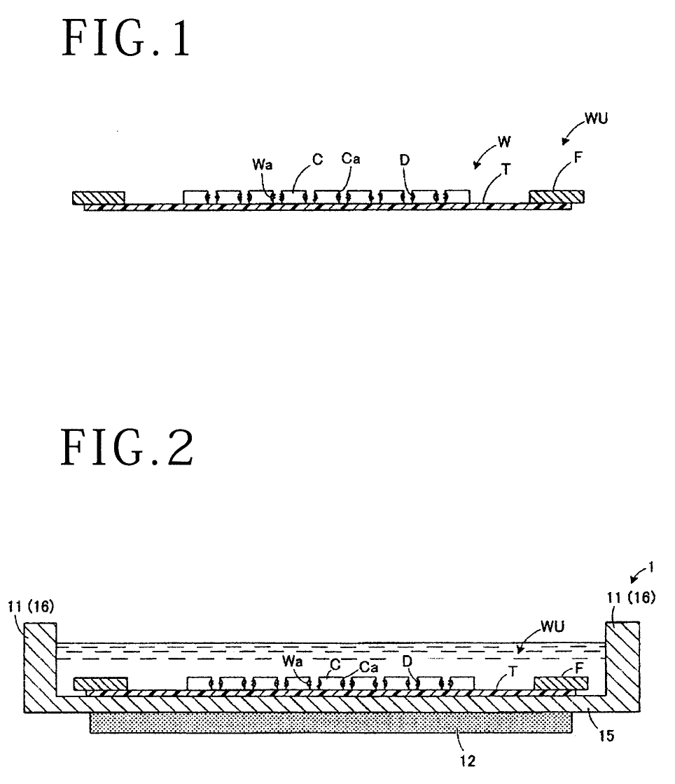

A cleaning method according to an embodiment of the present invention will be described below with reference to the accompanying drawings. FIG. 1 is a schematic cross-sectional view of an object to be cleaned by the cleaning method according to the embodiment of the present invention. In FIG. 1, the object to be cleaned is illustrated as having a plurality of chips bonded to an adhesive tape serving as a holding member. However, the object to be cleaned may have a plurality of chips bonded to a support board serving as a holding member.

As shown in FIG. 1, the object to be cleaned includes a wafer W which includes modified layers Wa formed along projected dicing lines by laser beam processing and which is divided into individual chips C, starting from the modified layers Wa. The chips C include the modified layers Wa on side faces Ca thereof, and are bonded to a holding member T such as an adhesive tape or the like with spaces or gaps formed between adjacent ones of the chips C. According to the present embodiment, the chips C that are spaced apart from each other and the holding member T to which the chips C are bonded are combined together into an object WU to be cleaned. The divided chips C are transported while they are supported on an annular frame F through the holding member T.

The modified layers Wa refer to areas whose mechanical strength is made lower than the surrounding portions by the application of a laser beam to the wafer W to change physical properties including density, refractive index, mechanical strength, etc. of the areas from those of the surrounding portions. The modified layers Wa may be fused areas, cracked areas, dielectric breakdown areas, changed-refractive-index areas, or areas including a mixture of those areas, for example. The chips C may include chips divided from a semiconductor wafer of silicon, gallium arsenide, or the like in which modified layers Wa are formed, or chips divided from an optical device wafer of ceramics, glass, sapphire, or like in which modified layers Wa are formed.

Modified layer debris D remains on the surfaces of the modified layers Wa which are exposed on the side faces Ca of the chips C, and the modified layer debris D tends to contaminate the inside of the apparatus involved in subsequent steps. The divided chips C are cleaned by a spinner. However, the modified layer debris D left on the side faces Ca cannot be removed by the spinner only. Though a method of picking up the chips C from the holding member T and individually cleaning the side faces Ca has been studied, the method has proven problematic in that the period of time required to clean the chips C is too long. For the above reasons, it has been customary to remove the modified layer debris D from the side faces Ca by plasma etching or the like rather than cleaning. The plasma etching is disadvantages in that it requires a plasma etching apparatus, resulting in an increased cost of equipment, and the number of steps required is increased by the plasma etching.

It has thus been generally recognized in the art that it is difficult to remove the modified layer debris D left on the surfaces of the modified layers Wa which are exposed on the side faces Ca of the chips C only by cleaning the chips C with cleaning water. The inventor of the present invention has tried to ultrasonically clean the object WU, and has found that an outstanding cleaning effect can be achieved by ultrasonically cleaning the object WU in the presence of a cleaning liquid containing a surface active agent. In the cleaning method according to the present embodiment, the object WU is immersed in a cleaning liquid containing a surface active agent, and ultrasonic waves are applied to the cleaning liquid to remove the modified layer debris D from the side faces Ca of the chips C on the basis of a synergistic effect of the ultrasonic cleaning process and the surface active agent.

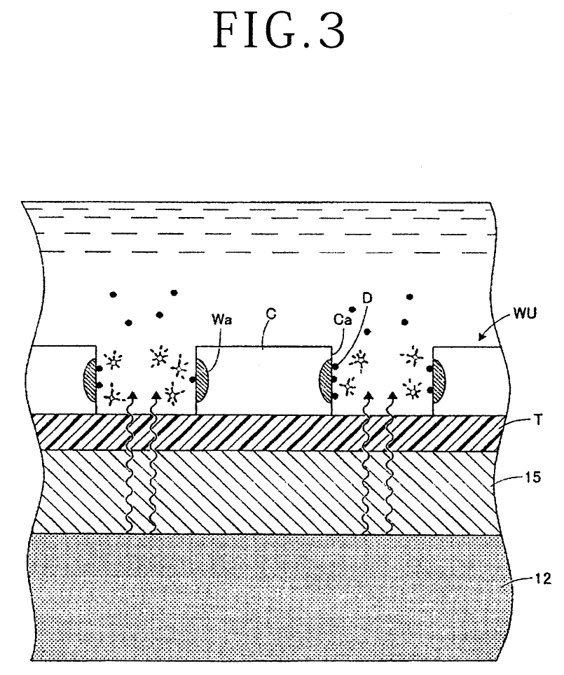

The cleaning method according to the present invention will hereinafter be described in detail below. FIG. 2 is a schematic cross-sectional view of a cleaning apparatus for carrying out the cleaning method according to the embodiment, and FIG. 3 is an enlarged fragmentary cross-sectional view illustrative of the manner in which chips are cleaned by the cleaning method according to the embodiment. The cleaning apparatus to be described below is illustrated by way of example only, and the present invention is not limited to the illustrated structural details of the cleaning apparatus. The cleaning apparatus may be modified insofar as it is capable of ultrasonically cleaning an object.

As shown in FIG. 2, the cleaning apparatus, denoted by 1, is arranged to ultrasonically clean the object WU that is immersed in a cleaning liquid stored in a cleaning tank 11. Ultrasonic oscillating means 12 is mounted on a bottom 15 of the cleaning tank 11 for propagating ultrasonic waves into the cleaning liquid. In the cleaning liquid, the ultrasonic waves change the pressure of the cleaning liquid into an alternatively compressional and rarefactional pattern, causing cavitation in the cleaning liquid to act on the side faces Ca of the chips C. The ultrasonic oscillating means 12 may include a Langevin-type vibrator or a bimorph-type vibrator, for example. The frequency of the ultrasonic oscillating means 12 should preferably be in the range from 20 Hz to 60 Hz.

To the cleaning liquid, there is added a surface active agent for intensifying the cleaning effect of the ultrasonic cleaning process. The surface active agent may be “MAMA LEMON” (registered trademark), “JOY” (registered trademark), or “STAY CLEAN A” (manufactured by DISCO Corporation). The concentration of the surface active agent should preferably be in the range from 0.01% to 70%. By immersing the object WU in the cleaning liquid thus prepared, the modified layer debris D is well peeled off the side faces Ca of the chips C by the action of the cavitation and the surface active agent. The ultrasonic oscillating means 12 may be mounted on a side 16, rather than the bottom 15, of the cleaning tank 11, for example.

As shown in FIG. 3, while the object WU to be cleaned is being immersed in the cleaning tank 11 (see FIG. 2), the cleaning liquid finds its way into and stays in the spaces between the chips C of the object WU. When the ultrasonic oscillating means 12 propagates ultrasonic waves into the cleaning liquid, changes in the sound pressure of the ultrasonic waves cause cavitation to be produced in the cleaning liquid in the spaces between the chips C. Shock waves of the cavitation act on the side faces Ca of the chips C, breaking the modified layer debris D on the side faces Ca. The ultrasonic waves also intensively vibrate the molecules of the cleaning liquid, peeling the modified layer debris D that has been broken by the cavitation off the side faces Ca.

Since the ultrasonic oscillating means 12 is mounted on the bottom 15 of the cleaning tank 11, the ultrasonic waves from the ultrasonic oscillating means 12 are propagated toward the surface of the cleaning liquid while causing cavitation in the spaces between the chips C. Consequently, the modified layer debris D peeled off the side faces Ca tends to flow toward the surface of the cleaning liquid, and becomes less liable to enter the spaces between the chips C. In addition, as the ultrasonic oscillating means 12 is positioned opposite the object WU across the bottom 15 of the cleaning tank 11, there are not many portions which interfere with the ultrasonic waves from the ultrasonic oscillating means 12. Accordingly, the ultrasonic waves from the ultrasonic oscillating means 12 can reach the side faces Ca of the chips C without being significantly attenuated.

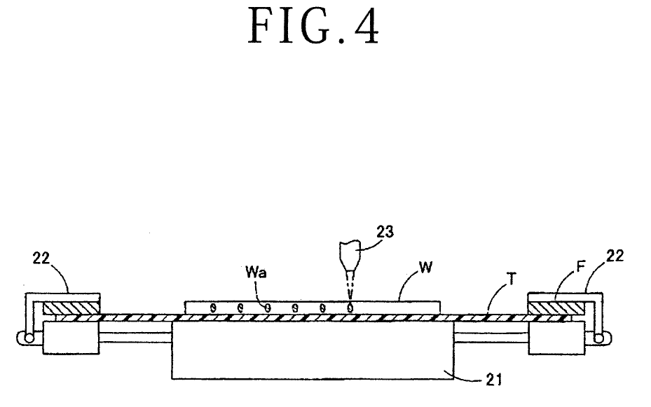

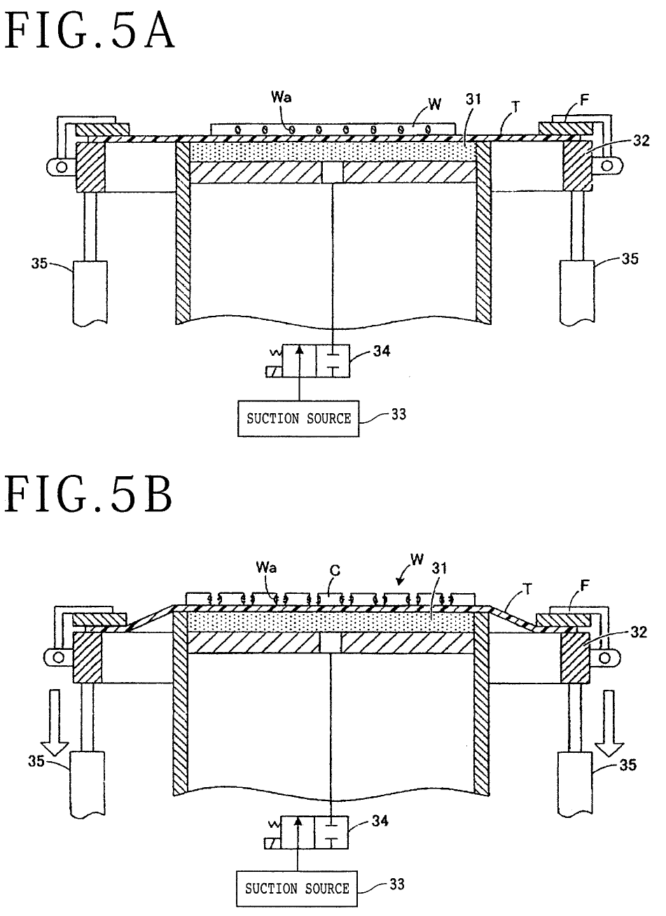

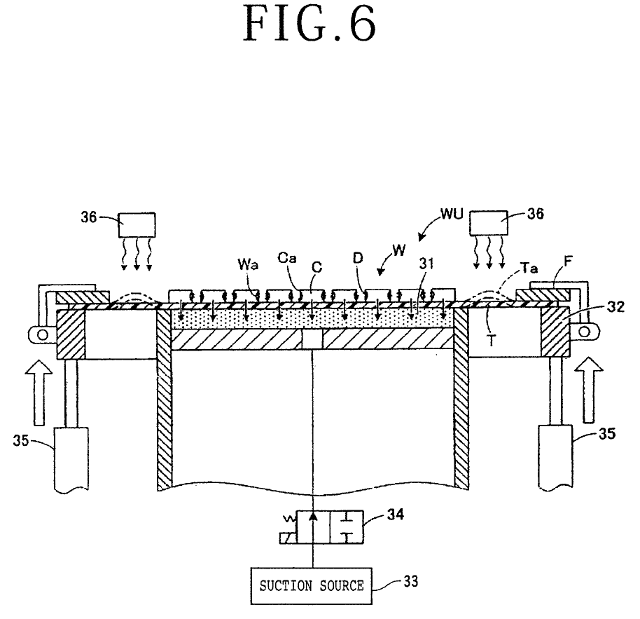

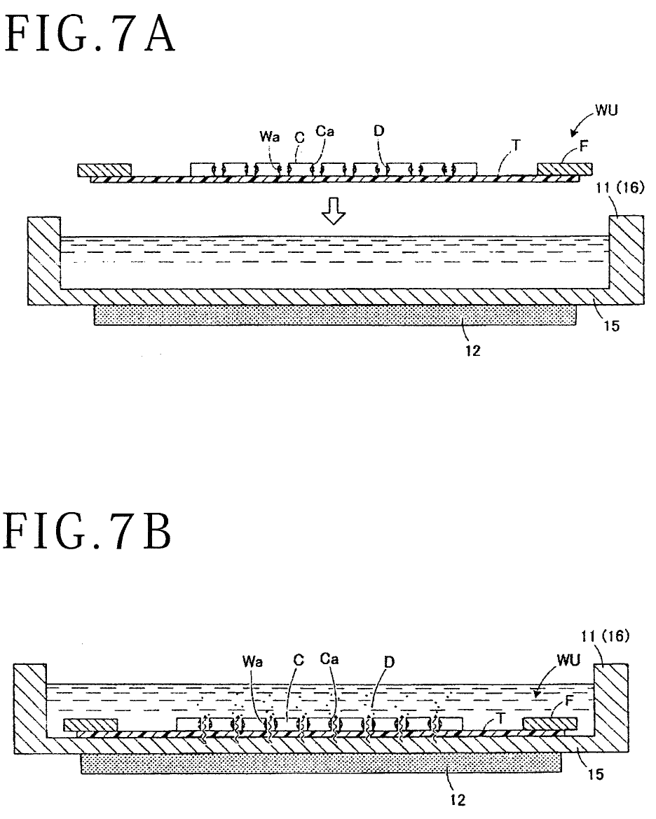

A sequence of processing steps on the object to be cleaned will be described below with reference to FIGS. 4 through 7B. FIG. 4 is a cross-sectional view showing by way of example a modified layer forming step of the cleaning method according to the embodiment. FIGS. 5A and 5B are cross-sectional views showing by way of example a dicing step of the cleaning method according to the embodiment. FIG. 6 is a cross-sectional view showing by way of example an inter-chip space holding step of the cleaning method according to the embodiment. FIGS. 7A and 7B are cross-sectional views showing by way of example a placing step and a cleaning step, respectively, of the cleaning method according to the embodiment.

As shown in FIG. 4, a modified layer forming step is initially carried out. In the modified layer forming step, the wafer W is held on a holding table 21 of a laser processing apparatus by the holding member T, and the annular frame F on the peripheral edge the wafer W is held by clamps 22. A beam emission port of a processing head 23 is positioned in alignment with one of the projected dicing lines of the wafer W, and then the processing head 23 applies a laser beam through the beam emission port to the wafer W. The laser beam has a wavelength that permeates the wafer W, and is focused within the wafer W. The wafer W and the processing head 23 are relatively moved to form modified layers Wa within the wafer W, from which the wafer W will start to be divided into chips C.

Then, as shown in FIG. 5A, the modified layer forming step is followed by a dicing step. In the dicing step, the wafer W is placed on a holding table 31 by the holding member T, and the annular frame F on the peripheral edge the wafer W is held by an annular frame holder 32. The holding table 31 is greater in diameter than the wafer W, and the portion of the holding member T which lies between the wafer W and the annular frame F has a lower side contacted by the outer peripheral edge of the holding table 31. In the dicing step, an on-off valve 34 connected between the holding table 31 and a suction source 33 is closed, blocking a suction force from the suction source 33 to the holding table 31 so that the holding member T will be allowed to expand.

As shown in FIG. 5B, the frame holder 32 which is supported by lifting and lowering means 35 is moved downwardly thereby, lifting the holding table 31 relative to the frame holder 32. The holding table 31 and the frame holder 32 are spaced from each other, expanding the holding member T radially outwardly thereby to apply an external force to the modified layers Wa (see FIG. 5A) in the wafer W through the holding member T. The wafer W is now divided into individual chips C, starting from the modified layer Wa whose mechanical strength has been lowered. The holding member T is stretched until adjacent ones of the chips C are completely spaced from each other, whereupon spaces are formed between the chips C.

Then, as shown in FIG. 6, the dicing step is followed by an inter-chip space holding step. In the inter-chip space holding step, the frame holder 32 is moved upwardly to bring the holding table 31 relatively closely to the frame holder 32, canceling the expansion of the holding member T. As the holding member T is released from tension, the portion of the holding member T which lies between the wafer W and the annular frame F develops a slackening Ta. In the inter-chip space holding step, the on-off valve 34 between the holding table 31 and the suction source 33 is open, supplying a suction force from the suction source 33 to the holding table 31 in order to prevent the spaces between the chips C from decreasing due to the cancelation of the expansion of the holding member T.

Heaters 36, which are positioned above the slackening Ta of the holding member T, heat the slackening Ta, thereby heat-shrinking the same. Since only the portion of the holding member T which lies between the wafer W and the annular frame F is heat-shrunk, the chips C are fixed in position while the spaces between the adjacent ones of the chips C are maintained even when the holding table 31 cancels its suction holding operation. In this manner, there is produced an object WU to be cleaned where the wafer W has been divided into the individual chips C with the spaces formed therebetween. Modified surface layers are exposed on the side faces Ca of each of the chips C, and modified layer debris D is formed on the modified surface layers.

Then, as shown in FIG. 7A, the inter-chip holding step is followed by a placing step. In the placing step, the object WU to be cleaned is placed in the cleaning tank 11 that is filled with a cleaning liquid, and is immersed in the cleaning liquid. The chips C of the object WU and the ultrasonic oscillating means 12 are now disposed opposite each other across the bottom 15 of the cleaning tank 11. The cleaning liquid contains a surface active agent of a predetermined concentration for intensifying the cleaning effect of an ultrasonic cleaning process.

Then, as shown in FIG. 7B, the placing step is followed by a cleaning step. In the cleaning step, the ultrasonic oscillating means 12 propagates ultrasonic waves into the cleaning liquid through the bottom 15 of the cleaning tank 11. The ultrasonic waves cause cavitation that acts on the side faces Ca of the chips C in the cleaning liquid. As described above, the cleaning liquid contains the surface active agent that makes it more suitable for the ultrasonic cleaning process. The modified layer debris D on the side faces Ca of the chips C is well peeled off due to a synergistic effect of the cavitation of the ultrasonic cleaning process and the surface active agent. Inasmuch as the object WU to be cleaned is immersed in the cleaning liquid in the cleaning tank 11 and the plural chips C are simultaneously ultrasonically cleaned, the period of time required to clean the chips C is reduced.

The object WU that has been ultrasonically cleaned is transported to a spinner table (not shown), on which it is cleaned by a spinner while pure water is being applied to the object WU. The surface active agent and the modified layer debris D which have been left on the object WU are now washed away.

### Inventive Examples

Inventive examples will be described below. In the inventive examples, objects WU to be cleaned (see FIG. 3) were cleaned under different cleaning conditions, and the linear densities of the modified layer debris D (see FIG. 3) left on the side faces Ca of the cleaned chips C were confirmed. The linear densities were calculated by pressing adhesive tapes against the side faces Ca of the cleaned chips C and image-processing the adhesive tapes to which the modified layer debris D has been transferred. As the cleaning conditions, there were carried out three types of cleaning processes including no cleaning process, a spinner cleaning, and an ultrasonic cleaning process. In the spinner cleaning process, the chips C were cleaned by pure water. In the ultrasonic cleaning process, the chips C were ultrasonically cleaned at a frequency of 20 kHz in cleaning liquids containing 11 liters of pure water and 50 ml of undiluted surface active agents a through d added thereto. “STAY CLEAN-A” (manufactured by DISCO Corporation) was used as the surface active agent a. “JOY” (registered trademark) was used as the surface active agent b. An experimental liquid (manufactured by DISCO Corporation) was used as the surface active agent c. “MAMA LEMON” (registered trademark) was used as the surface active agent d.

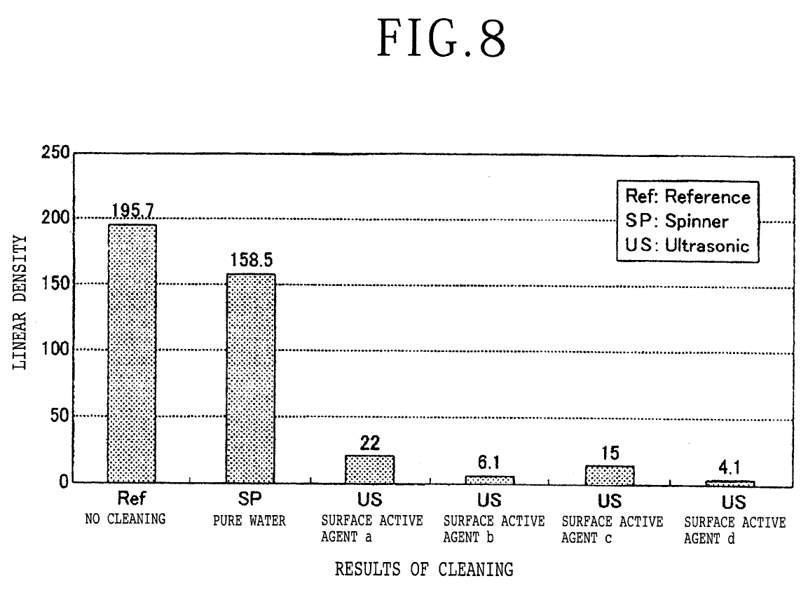

As a consequence, the results shown in FIG. 8 were obtained. In the no cleaning process and the spinner cleaning process by pure water, the linear densities of the modified layer debris D left on the side faces Ca of the chips C were high. In the ultrasonic cleaning process using the surface active agent, the linear densities of the modified layer debris D left on the side faces Ca of the chips C were greatly reduced. It was confirmed that the surface active agents b and d in particular reduced the linear densities of the modified layer debris D compared with the surface active agents a and c. Therefore, it was confirmed that the ultrasonic cleaning process and the surface active agent in combination were capable of well cleaning away the modified layer debris D on the modified surface layers on the side faces Ca of the chips C.

In the cleaning method according to the present invention, as described above, the object WU to be cleaned is immersed in the cleaning liquid containing the surface active agent, and the spaces between the adjacent ones of the chips C of the object WU are filled with the cleaning liquid. When ultrasonic waves are applied to the cleaning liquid between the chips C, the modified layer debris D is well peeled off the side faces Ca of the chips C by the synergistic effect of the ultrasonic cleaning process and the surface active agent. Since all the chips C of the object WU can simultaneously be cleaned, the period of time required to clean the chips C can be greatly shortened compared with a process wherein the chips C are picked up one by one from the object WU and individually cleaned.

The present invention is not limited to the above embodiment, but various changes and modifications may be made therein. The above embodiment is not limited to the sizes and shapes illustrated in the accompanying drawings, but may be modified insofar as the advantages of the present invention can be achieved. Moreover, other changes and modifications may be made without departing from the scope of the object of the present invention.

For example, in the above embodiment, the ultrasonic oscillating means 12 is disposed outside of the cleaning tank 11. However, the ultrasonic oscillating means 12 is not limited to such an arrangement. The ultrasonic oscillating means 12 may be disposed in a position where it can generate ultrasonic waves in the cleaning liquid. For example, the ultrasonic oscillating means 12 may be mounted in the cleaning tank 11. In the above embodiment, the modified layer debris D is not limited to debris produced on the modified surface layer on the side faces Ca of the chip C, but may include debris produced when the chips C are diced.

In the above embodiment, the wafer W is diced by expanding the holding member T in the dicing step. However, the dicing step is not limited to such a process. The dicing step may only require the wafer W to be diced into individual chips C, starting from the modified layers Wa, and the wafer W may be diced into individual chips C by breaking.

In the above embodiment, the spaces between the adjacent ones of the chips C are held by removing the slackening Ta with heat shrinking in the inter-chip holding step. However, the inter-chip holding step is not limited to such a process. The inter-chip holding step may only require the spaces between the individual chips C to be held, and the spaces between the individual chips C may be held by re-bonding the annular frame to the holding member T.

In the above embodiment, the object WU to be cleaned is placed on the bottom 15 of the cleaning tank 11 in the placing step. However, the placing step is not limited to such a process. The placing step may only require the object WU to be immersed in the cleaning tank 11 filled with the cleaning liquid, and the object WU may be supported in a position spaced upwardly from the bottom 15 of the cleaning tank 11.

In the above embodiment, the plural chips C are supported on the annular frame F by the holding member T. However, the plural chips C are not limited to such an arrangement. The plural chips C may be integrally bonded to the holding member T, and the annular frame F may not be bonded to the holding member T.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A method of cleaning an object in which a plurality of chips, with modified layers formed on side faces of each of the chips, are integrally bonded to a holding member with spaces formed between adjacent ones of the chips, using a cleaning apparatus having a cleaning tank storing a cleaning liquid which contains a surface active agent and ultrasonic oscillating means disposed on a bottom or a side of the cleaning tank, said method comprising:
a placing step of placing the object in the cleaning tank and immersing the object in the cleaning liquid; and
a cleaning step of cleaning away modified layer debris on side faces of the chips with ultrasonic waves generated by the ultrasonic oscillating means after performing the placing step.
